(19) United States
(12) Patent Application Publication
(10) Pub. No.: US 2026/0371853 A1
(43) Pub. Date: Nov. 19, 2026

(54) DISPLAY PANEL AND MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Fan ZHANG, Beijing (CN); Kai ZHANG, Beijing (CN); Dongjie WU, Beijing (CN); Hailong YAN, Beijing (CN); Huaping SUN, Beijing (CN); Qi ZHANG, Beijing (CN)

(21) Appl. No.: 19/145,897

(22) PCT Filed: Jun. 14, 2024
(86) PCT No.: PCT/CN2024/099321

§ 371 Date: Jul. 4, 2025

(30) Foreign Application Priority Data
Jul. 31, 2023 (CN) 202310954364.2

(51) Int. Cl. H10K 59/122; H10K 59/12

(52) U.S. Cl. CPC H10K 59/122; H10K 59/1201

(57) ABSTRACT

The embodiments of the present disclosure belong to the technical field of display. Provided are a display panel and a manufacturing method therefor, and a display device. The display panel comprises: a base substrate, a light-emitting functional layer, an electrostatic protection structure and a plurality of internal isolation structures. The base substrate is provided with a display region, a first isolation region and an opening region. The light-emitting functional layer is located on a first surface of the base substrate, a plurality of light-emitting units are arranged in an array in the display region, and first electrodes of the plurality of light-emitting units are connected. The plurality of internal isolation structures are located on the first surface and within the first isolation region, and comprise at least one first isolation structure, the first isolation structure comprising a first isolation ring, which is located on the same layer as the first electrodes and is insulated therefrom. The electrostatic protection structure is located in the first isolation region and located on a side of the plurality of internal isolation structures that is close to the base substrate. The embodiments of the present disclosure can ameliorate a poor display due to the breakdown of the first isolation ring by charge accumulation.

### CROSS-REFERENCE TO RELATED APPLICATIONS

The present disclosure is a U.S. national phase application based on PCT/CN 2024/099321, filed on Jun. 14, 2024, which claims priority to Chinese Patent Application No. 202310954364.2, filed on Jul. 31, 2023, and entitled “DISPLAY PANEL AND MANUFACTURING METHOD THEREFOR, AND DISPLAY DEVICE”, both of which are incorporated by reference herein.

### TECHNICAL FIELD

The present disclosure relates to the field of display technologies, and in particular, relates to a display panel and a manufacturing method therefor, and a display device.

### BACKGROUND

Display devices are widely used in people's daily life, such as mobile phones, monitors, tablet computers, etc. Display panels are an important part of display devices.

### SUMMARY

The present disclosure provides a display panel and a manufacturing method therefor, and a display device.

In one aspect, a display panel is provided. The display panel includes a base substrate, a light-emitting functional layer, an electrostatic protection structure, and a plurality of internal isolation structures; wherein the base substrate has a display region, a first isolation region, and an opening region, wherein the display region surrounds the opening region, and the first isolation region is disposed between the opening region and the display region; the light-emitting functional layer is disposed on a first surface of the base substrate and includes a plurality of light-emitting units, wherein the plurality of light-emitting units are arranged in an array in the display region, and first electrodes of the plurality of light-emitting units are connected; the plurality of internal isolation structures are disposed in the first isolation region and on the first surface, the plurality of internal isolation structures are all in a ring shape and surround the opening region, and the plurality of internal isolation structures include at least one first isolation structure including a first isolation ring, wherein the first isolation ring is in a same layer as the first electrodes and is insulated from the first electrodes; and the electrostatic protection structure is disposed at least in the first isolation region and on a side of the plurality of internal isolation structures close to the base substrate.

In some embodiments, the electrostatic protection structure is an electrostatic shielding structure; and an orthographic projection of the first isolation structure on the first surface is within an orthographic projection of the electrostatic shielding structure on the first surface.

In some embodiments, the electrostatic shielding structure includes one electrostatic shielding layer, or includes a plurality of electrostatic shielding layers stacked in a direction perpendicular to the first surface; wherein the electrostatic shielding layer includes an electrostatic shielding ring; or, the electrostatic shielding layer includes a plurality of electrostatic shielding rings, the plurality of electrostatic shielding rings being concentric rings and orthographic projection of the plurality of electrostatic shielding rings on the first surface do not overlap each other.

In some embodiments, the electrostatic protection structure is an electrostatic discharge structure, wherein the first isolation ring is electrically connected to the electrostatic discharge structure.

In some embodiments, the electrostatic discharge structure includes one electrostatic discharge layer or includes a plurality of electrostatic discharge layers that are stacked in a direction perpendicular to the first surface and are connected to each other; and each of the electrostatic discharge layers is electrically connected to a voltage signal source.

In some embodiments, the display panel further includes a driver circuit layer, wherein the driver circuit layer is disposed between the light-emitting functional layer and the base substrate; and the electrostatic protection structure is in a same layer as at least one non-insulating layer of the driver circuit layer.

In some embodiments, the driver circuit layer includes a plurality of thin film transistors; wherein the plurality of thin film transistors includes low-temperature polycrystalline silicon thin film transistors and metal oxide thin film transistors, and the non-insulating layer includes at least one of a shading layer, a first gate layer, a second gate layer, and a third gate layer; or, the plurality of thin film transistors includes low-temperature poly crystalline silicon thin film transistors, and the non-insulating layer includes at least one of a first gate layer and a second gate layer.

In some embodiments, the first isolation structure further includes a first isolation pillar and a first insulation structure; wherein the first isolation pillar has a top surface away from the base substrate, a bottom surface close to the base substrate, and a first sidewall connecting the top surface and the bottom surface, and the first sidewall faces towards the opening region; the first insulation structure includes a first insulation portion and a second insulation portion that are connected, wherein the first insulation portion is disposed on the top surface, and the second insulation portion is disposed on the first sidewall; and the first isolation ring includes a first conductive portion and a second conductive portion that are connected in sequence, wherein the first conductive portion is disposed on a surface of the first insulation portion away from the base substrate, and the second conductive portion is disposed on a surface of the second insulation portion facing towards the opening region.

In some embodiments, the first isolation structure further includes a first isolation pillar and a first insulation structure; wherein the first isolation pillar has a top surface away from the base substrate, a bottom surface close to the base substrate, and a first sidewall connecting the top surface and the bottom surface, and the first sidewall faces towards the opening region; the first insulation structure includes a first insulation portion and a second insulation portion that are connected, wherein the first insulation portion is disposed on the top surface, and the second insulation portion is disposed on the first sidewall; and the first isolation ring includes a first conductive portion and a second conductive portion that are connected in sequence, wherein the first conductive portion is disposed on a surface of the first insulation portion away from the base substrate, the second conductive portion is disposed on a surface of the second insulation portion facing toward the opening region, and the second conductive portion is electrically connected to the electrostatic discharge structure.

In some embodiments, the display panel further includes an isolation dam, wherein the isolation dam is disposed between the first isolation region and the opening region, and the isolation dam is disposed on the first surface; and an internal isolation structure among the plurality of internal isolation structures that is closest to the opening region is an edge isolation structure; wherein the edge isolation structure includes an edge isolation pillar, an edge insulation structure, and an edge isolation ring, wherein the edge isolation pillar has a top surface away from the base substrate, a bottom surface close to the base substrate, and a first sidewall connecting the top surface and the bottom surface; the first sidewall faces towards the opening region; and the edge insulation structure includes a first edge insulation portion and a second edge insulation portion that are connected, wherein the first edge insulation portion is disposed on the top surface, the second edge insulation portion is disposed on the first sidewall, the second edge insulation portion is connected to an insulation block disposed on a side of the isolation dam close to the base substrate; and the edge isolation ring includes a first edge conductive portion and a second edge conductive portion that are connected in sequence, wherein the first edge conductive portion is disposed on a surface of the first edge insulation portion away from the base substrate, the second edge conductive portion is disposed on a surface of the second edge insulation portion facing towards the opening region, and a side of the second edge conductive portion away from the first edge conductive portion is connected to an electrode block disposed on a side of the isolation dam away from the base substrate.

In some embodiments, the base substrate further has a second isolation region disposed between the first isolation region and the opening region, and the display panel further includes a plurality of external isolation structures disposed in the second isolation region and on the first surface; and wherein the plurality of external isolation structures includes at least one second isolation structure, and the second isolation structure is of a same structure as the first isolation structure.

In some embodiments, the base substrate further has a second isolation region disposed between the first isolation region and the opening region, and the display panel further includes a plurality of external isolation structures disposed in the second isolation region and on the first surface; and wherein an orthographic projection of at least a portion of the plurality of external isolation structures is within an orthographic projection of the electrostatic protection structure on the first surface.

In some embodiments, the plurality of external isolation structures further includes a fourth isolation structure, and a height of the fourth isolation structure is greater than heights of external isolation pillars except the fourth isolation structure.

In another aspect, a method for manufacturing a display panel is provided. The method includes: providing a base substrate, wherein the base substrate has a display region, a first isolation region, and an opening region, wherein the display region surrounds the opening region, and the first isolation region is disposed between the opening region and the display region; and forming a light-emitting functional layer, an electrostatic protection structure, and a plurality of internal isolation structures on a first surface of the base substrate; wherein the light-emitting functional layer includes a plurality of light-emitting units arranged in an array in the display region, first electrodes of the plurality of light-emitting units being connected, the plurality of internal isolation structures are disposed in the first isolation region, the plurality of internal isolation structures are all in a ring shape and surround the opening region, the plurality of internal isolation structures include at least one first isolation structure, the first isolation structure includes a first isolation ring, wherein the first isolation ring is in a same layer as the first electrode and is insulated from the first electrode, and the electrostatic protection structure is disposed in the first isolation region and on a side of the plurality of internal isolation structures close to the base substrate.

In still another aspect, a display device is provided. The display device includes a power supply circuit and the display panel as described above, wherein the power supply circuit supplies power to the display panel.

### BRIEF DESCRIPTION OF DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a schematic structural diagram of a display device according to some embodiments of the present disclosure;

FIG. 2 is a schematic cross-sectional structure diagram of the display device in FIG. 1 along line AA;

FIG. 3 is an enlarged structural schematic diagram of part B in FIG. 1;

FIG. 4 is a schematic cross-sectional structure diagram of a display panel along line CC in FIG. 3 according to some embodiments of the present disclosure;

FIG. 5 is a schematic cross-sectional structure diagram of another display panel according to some embodiments of the present disclosure;

FIG. 6 is a schematic cross-sectional structure diagram of another display panel according to some embodiments of the present disclosure;

FIG. 7 is a schematic cross-sectional structure diagram of another display panel according to some embodiments of the present disclosure;

FIG. 8 is a schematic cross-sectional structure diagram of another display panel according to some embodiments of the present disclosure;

FIG. 9 is a schematic cross-sectional structure diagram of another display panel according to some embodiments of the present disclosure;

FIG. 10 is a schematic cross-sectional structure diagram of another display panel according to some embodiments of the present disclosure;

FIG. 11 is a schematic cross-sectional structure diagram of another display panel according to some embodiments of the present disclosure; and FIG. 12 is a flowchart of a method for manufacturing a display panel according to some embodiments of the present disclosure.

### REFERENCE NUMERALS

100, display panel; 200, housing; 300, cover plate;
400, circuit board; 500, electronic device;
103, light-emitting side; 104, non-light-emitting side;
G1-G4, first isolation structure to fourth isolation structure; G1*, edge isolation structure;
1, display region; 2, first isolation region; 3, opening region; 4, second isolation region; 5, isolation dam;
6, first isolation pillar; 6*, edge isolation pillar; 7, second isolation pillar;
8, third isolation pillar; 9a, fourth isolation pillar; 9b, fifth isolation pillar;
10, driver circuit layer; 11, electrostatic protection structure;
111, electrostatic shielding structure; 1111, electrostatic shielding layer; 1111a, electrostatic shielding ring;
112, electrostatic discharge structure; 1121, electrostatic discharge layer;
12, passivation layer; 121, first insulation structure;
121*, edge insulation structure; 122, second insulation structure;
123, third insulation structure; 124, fourth insulation structure;
1211, first insulation portion 1212, second insulation portion;
1211*, first edge insulation portion 1212*, second edge insulation portion;
1221, third insulation portion; 1222, fourth insulation portion;
13, light shielding layer; 14, first gate layer; 15, second gate layer; 16, third gate layer;
17, base substrate; D, first surface;
18, buffer layer; 19, first active layer;
20, light-emitting functional layer; 21, first electrode;
211, first isolation ring; 211*, edge isolation ring; 212, second isolation ring;
213, first bottom isolation ring; 215*, edge bottom isolation ring;
216, third isolation ring; 217, fourth isolation ring;
22, pixel definition layer; 23, light-emitting layer;
2111, first conductive portion; 2112, second conductive portion;
2111*, first edge conductive portion; 2112*, second edge conductive portion;
2121, third conductive portion; 2122, fourth conductive portion;
30, first gate insulating layer; 31, first insulating layer; 32, second gate insulating layer;
33, third gate insulating layer; 34, interlayer dielectric layer; 35, first source-drain electrode layer;
36, first planarization layer; 37, second source-drain electrode layer; 38, second planarization layer;
39, second active layer; 40, first inorganic encapsulation layer; 41, first organic encapsulation layer;
42, second inorganic encapsulation layer; 43, touch insulating layer; 44, touch organic protection layer;
45, second organic encapsulation layer.

### DETAILED DESCRIPTION

To make the objective, technical solutions, and advantages of the present disclosure clearer, embodiments of the present disclosure will be described in further detail below in conjunction with the accompanying drawings.

The terms used in the embodiments of the present disclosure are only used to explain the embodiments of the present disclosure, and are not intended to limit the present disclosure. Unless otherwise defined, the technical terms or scientific terms used in the embodiments of the present disclosure should be the usual meanings understood by people with ordinary skills in the field to which the present disclosure belongs. The “first,” “second,” “third,” and similar words used in the application specification and claims of the present disclosure do not indicate any order, quantity or importance, but are only used to distinguish different components. Similarly, similar words such as “one” or “a” do not indicate quantitative restrictions, but indicate that there is at least one. Similar words such as “include” or “comprise” mean that the elements or objects appearing in front of “include” or “comprise” cover the elements or objects listed after “include” or “comprise” and their equivalents, and do not exclude other elements or objects. The directional terms mentioned in the present disclosure, such as “top, ”“bottom,” “up,” “down,” “left,” or “right”, etc., are only referenced to the directions of the drawings. Therefore, the directional terms used are for better and clearer explanation and understanding of the embodiments of the present disclosure, rather than indicating or implying that the referred device or element should have a specific orientation, be constructed and operated in a specific orientation, and therefore cannot be understood as a limitation on the embodiments of the present disclosure.

In the related art, a display panel includes a base substrate, a light-emitting functional layer, and a plurality of internal isolation structures. The base substrate has a display region, a first isolation region and an opening region, the display region surrounds the opening region, and the first isolation region is located between the opening region and the display region. The light-emitting functional layer is located in the display region and on a first surface of the base substrate, and the light-emitting functional layer has a plurality of first electrodes connected. The plurality of internal isolation structures are located in the first isolation region and on the first surface of the base substrate, and at least one internal isolation structure includes a first isolation ring, the first isolation ring being in the same layer as the first electrode and being insulated from the first electrode.

However, the first isolation ring is prone to breakdown due to charge accumulation, thereby causing poor display.

The embodiments of the present disclosure provide a display device, which may be any product or component with a display function, such as a laptop computer, a mobile phone, a tablet computer, a television, a monitor, a wearable device, a digital photo frame, a navigator, or the like.

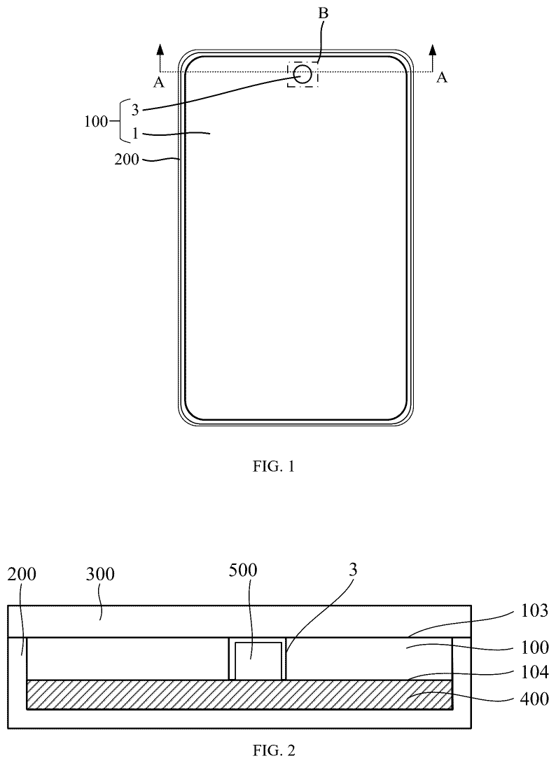

FIG. 1 is a schematic structural diagram of a display device according to some embodiments of the present disclosure. As shown in FIG. 1, the display device includes a display panel 100 and a power supply circuit (not shown in the drawings), and the power supply circuit supplies power to the display panel 100. The display panel 100 has a display region 1 and at least one opening region 3.

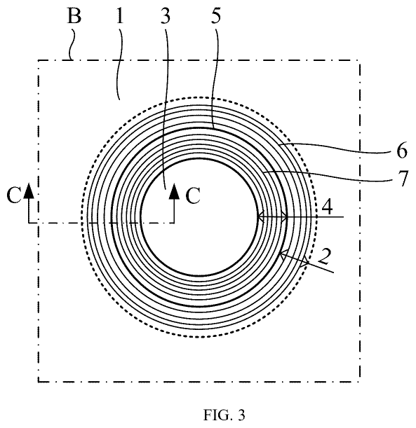

FIG. 2 is a schematic cross-sectional structure diagram of the display device in FIG. 1 along line AA. As shown in FIGS. 1 and 2, the display panel 100 includes a light-emitting side 103 and a non-light-emitting side 104 that are arranged opposite to each other. The display device may also include a housing 200, a cover plate 300, a circuit board 400, and an electronic device 500.

The electronic device 500 is disposed in the opening region 3. The electronic device 500 may be a camera module, a fingerprint module, or other modules that need to receive external light.

As shown in FIG. 2, the longitudinal section of the housing 200 may be, for example, U-shaped. The display panel 100 and the circuit board 400 are disposed in the housing 200, and the cover plate 300 is disposed at the opening of the housing 200.

There are many types of display panels 100, which can be selected according to actual needs.

Exemplarily, the display panel 100 may be an organic light emitting diode (OLED) display panel, a quantum dot light emitting diode (QLED) display panel, etc., which is not specifically limited in the embodiments of the present disclosure.

The following takes the display panel 100 as an OLED display panel as an example for illustration.

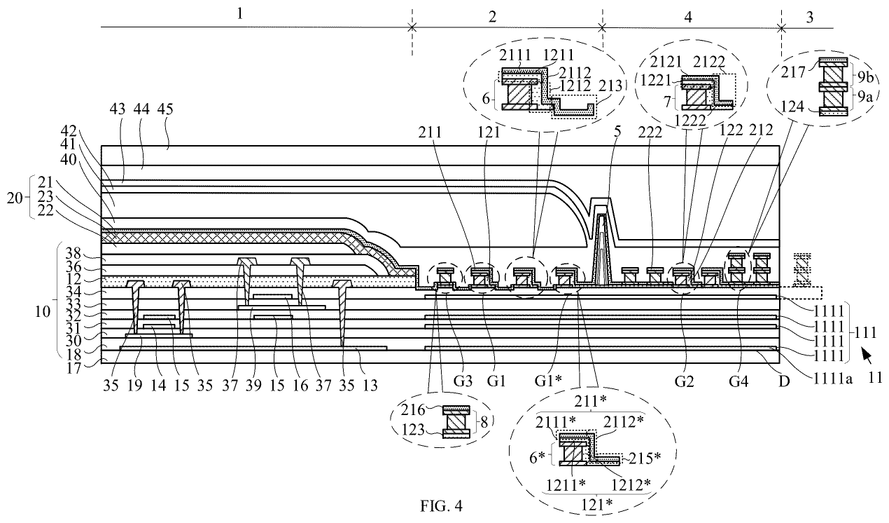

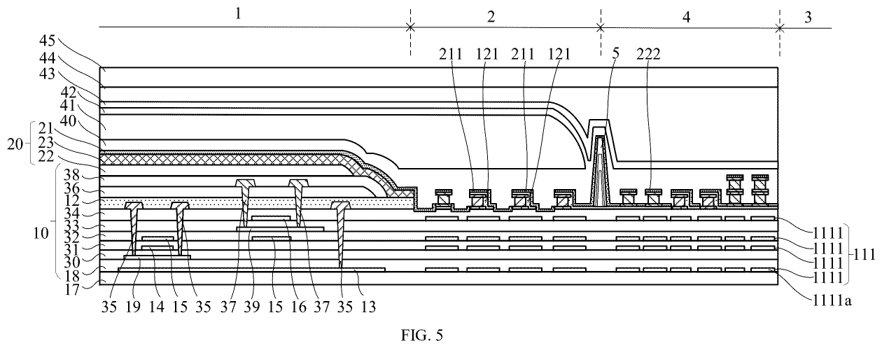

FIG. 3 is an enlarged structural schematic diagram of part B in FIG. 1, FIG. 4 is a schematic cross-sectional structure diagram of a display panel along line CC in FIG. 3 according to some embodiments of the present disclosure. As shown in FIGS. 3 and 4, the display panel 100 includes a base substrate 17, a light-emitting functional layer 20, an electrostatic protection structure 11, and a plurality of internal isolation structures. The base substrate has a display region 1, a first isolation region 2, and an opening region 3. The display region 1 surrounds the opening region 3, and the first isolation region 2 is disposed between the opening region 3 and the display region 1. Here, the display region 1 and the opening region 3 of the base substrate 17 correspond to the display region 1 and the opening region 3 of the display panel 100 in FIG. 1, respectively.

In the embodiments of the present disclosure, as shown in FIG. 4, the light-emitting functional layer 20 is disposed on the first surface D of the base substrate 17, and the light-emitting functional layer 20 includes a plurality of light-emitting units. The plurality of light-emitting units are arranged in an array in the display region 1, and the first electrodes 21 of the plurality of light-emitting units are connected. The plurality of internal isolation structures are disposed in the first isolation region 2 and on the first surface D, and each of the internal isolation structures is in a ring shape and surrounds the opening region 3. The plurality of internal isolation structures include at least one first isolation structure G1, the first isolation structure G1 includes a first isolation ring 211, and the first isolation ring 211 is in the same layer as the first electrode 21 and is insulated from the first electrode 21. The electrostatic protection structure 11 is disposed in the first isolation region 2 and on a side of the plurality of internal isolation structures close to the base substrate 17, and the electrostatic protection structure 11 is used to prevent the first isolation ring 211 from accumulating charge.

In the embodiments of the present disclosure, the same layer means formed by the same patterning process, or in contact with the same surface of the same film layer, or located on the same side of the same film layer, etc. Different layers mean formed by different patterning processes, or in contact with surfaces of different film layers, or located on different sides of the same film layer, etc.

In the first isolation region 2, if there is no electrostatic protection structure 11, in the process (such as film pasting, film peeling, etc.), the first isolation ring 211 near the opening region 3 is prone to charge accumulation, such that breakdown occurs at the first isolation ring 211. Here, “breakdown occurs at the first isolation ring 211” refers to the insulating layer (such as the light-emitting layer 23 below) between the first isolation ring 211 and the conductor (such as the first isolation pillar 6 below) is broken down. The heat energy released at the moment of breakdown may cause the packaging film layer to rupture and be damaged due to the sudden change of thermal expansion and contraction, thereby causing packaging failure. External water and oxygen invade the light-emitting layer in the light-emitting functional layer along the gaps in the packaging film layer, causing the light-emitting layer to emit abnormal light, thereby causing poor display. The poor display may be manifested as uneven display or even black spots. The arrangement of the electrostatic protection structure 11 can prevent the first isolation ring 211 from accumulating too much charge and causing electrostatic breakdown, thereby avoiding poor display caused by the breakdown.

In the embodiments of the present disclosure, as shown in FIG. 4, the electrostatic protection structure 11 is an electrostatic shielding structure 111. An orthographic projection of the first isolation structure GI on the first surface D is within an orthographic projection of the electrostatic shielding structure 111 on the first surface D. That is, the electrostatic shielding layer 1111 covers a plurality of first isolation structures G1, and the electrostatic shielding structure 111 can play an electrostatic shielding role at the first isolation ring 211, thereby preventing the first isolation ring 211 from being broken down due to excessive charge accumulation.

Optionally, the electrostatic shielding structure 111 includes one electrostatic shielding layer 1111, or the electrostatic shielding structure 111 includes a plurality of electrostatic shielding layers 1111 stacked in a direction perpendicular to the first surface D. The electrostatic shielding layer 1111 includes one electrostatic shielding ring 1111a.

In the embodiments shown in FIG. 4, the electrostatic shielding structure 111 includes four electrostatic shielding layers 1111, and each electrostatic shielding layer 1111 includes an electrostatic shielding ring 1111a. The electrostatic shielding ring 1111a is a complete ring structure. The electrostatic shielding ring 1111a surrounds the opening region 3. One electrostatic shielding ring 1111a, that is, a whole electrostatic shielding layer, not only covers the first isolation structure G1, but also covers the region between two adjacent first isolation structures G1. This full coverage design method has a more comprehensive shielding region, better effect in blocking external static interference, and is more beneficial to the uniformity of the upper film layer (such as the interlayer dielectric layer 34, the first source-drain layer 35, the passivation layer 12, etc. in the following text) of the film layer where the electrostatic shielding structure 111 is located. Here, “above” refers to the side of the electrostatic shielding structure 111 away from the base substrate 17.

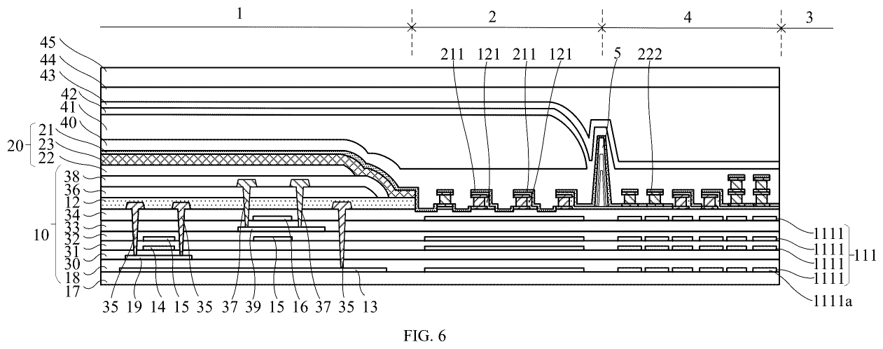

FIG. 5 is a schematic cross-sectional structure diagram of another display panel according to some embodiments of the present disclosure. The difference from the embodiments shown in FIG. 4 is that the structure of the electrostatic shielding layer 1111 is different. As shown in FIG. 5, the electrostatic shielding layer 1111 includes a plurality of electrostatic shielding rings 1111a, and orthographic projections of the plurality of electrostatic shielding rings 1111a of each electrostatic shielding layer 1111 on the first surface D do not overlap with each other, that is, the region of the first isolation region 2 having the first isolation structure G1 is covered in segments. Optionally, the electrostatic shielding layer 1111, as shown in FIG. 5, may only cover the first isolation structure G1, and not cover the region between two adjacent first isolation structures G1. Optionally, the electrostatic shielding layer 1111 may also cover the first isolation structure G1, and cover the region between two adjacent first isolation structures G1, that is, the distance between two adjacent electrostatic shielding rings 1111a is less than the distance between the correspondingly covered two adjacent first isolation structures G1. Segmented coverage can achieve the protection purpose in a targeted manner; and there is no large area of metal (i.e., circular metal with a large diameter-width). A large area of metal will bring loading to processes such as exposure and etching of other metal traces near the area. The process is complex and may cause problems where other metal traces cannot achieve the expected line width and line spacing, ultimately resulting in poor display. The smaller area of metal in segmented coverage can avoid the above problems as much as possible.

In the embodiments of the present disclosure, as shown in FIG. 4, the display panel 100 also includes a driver circuit layer 10, and the driver circuit layer 10 is disposed between the light-emitting functional layer 20 and the base substrate 17. The electrostatic protection structure 11 is disposed in the same layer as at least one non-insulating layer of the driver circuit layer 10. The electrostatic protection structure 11 is disposed in the same layer as the existing structure of the display panel 100, thereby saving process costs.

Exemplarily, the driver circuit layer 10 includes a plurality of thin film transistors (TFTs).

In some examples, the plurality of TFTs include low-temperature polysilicon TFTs and metal oxide TFTs. That is, the drive backplane composed of the driver circuit layer 10 and the base substrate 17 is a low-temperature polycrystalline oxide (LTPO) backplane. For the LTPO backplane, the non-insulating layer includes at least one of a light shielding layer 13, a first gate layer 14, a second gate layer 15, and a third gate layer 16.

The light shielding layer 13, the first gate layer 14, the second gate layer 15, and the third gate layer 16 are all film layers on a side of the first isolation structure 6 away from the first electrode layer 21, and thus can be used to simultaneously manufacture the electrostatic protection structure.

For example, in the embodiments shown in FIG. 4, the four electrostatic shielding layers 1111 are in the same layers as the light shielding layer 13, the first gate layer 14, the second gate layer 15, and the third gate layer 16, respectively.

Exemplarily, as shown in FIG. 4, the LTPO backplane includes a base substrate 17, a light shielding layer 13, a buffer layer 18, a first active layer 19, a first gate insulating layer 30, a first gate layer 14, a first insulating layer 31, a second gate layer 15, a second gate insulating layer 32, a second active layer 39, a third gate insulating layer 33, a third gate layer 16, an interlayer dielectric layer 34, a first source-drain electrode layer 35, a passivation layer 12, a first planarization layer 36, a second source-drain electrode layer 37, and a second planarization layer 38 that are stacked in sequence. The light-emitting functional layer 20 includes a second electrode layer (not shown), a pixel definition layer 22, a light-emitting layer 23, and a first electrode layer 21 that are stacked in sequence on the first surface D of the drive backplane. Optionally, the first electrode layer 21 is a cathode layer, and the second electrode layer is an anode layer. The display panel 100 includes a drive backplane, a light-emitting functional layer 20, and a first inorganic encapsulation layer 40, a first organic encapsulation layer 41, a second inorganic encapsulation layer 42, a touch layer, a touch insulating layer 43, a touch organic protection layer 44, and a second organic encapsulation layer 45 that are stacked in sequence on a side of the light-emitting functional layer 20 away from the first surface D.

The touch layer may be a self-capacitive touch structure or a mutual-capacitive touch structure, which is not limited in the present disclosure. The touch layer may be provided as required, and when the display panel does not require a touch function, the touch layer does not need to be provided.

In the embodiments of the present disclosure, as shown in FIG. 4, the first isolation structure G1 also includes a first isolation pillar 6 and a first insulation structure 121. The first isolation pillar 6 has a top surface away from the base substrate 17, a bottom surface close to the base substrate 17, and a first sidewall connecting the top surface and the bottom surface. The first sidewall faces towards the opening region 3. The first insulation structure 121 includes a first insulation portion 1211 and a second insulation portion 1212 that are connected, the first insulation portion 1211 is disposed on the top surface, and the second insulation portion 1212 is disposed on the first sidewall. The first isolation ring 211 includes a first conductive portion 2111 and a second conductive portion 2112 that are connected in sequence. The first conductive portion 2111 is disposed on the surface of the first insulation portion 1211 away from the base substrate 17, and the second conductive portion 2112 is disposed on the surface of the second insulation portion 1212 facing towards the opening region 3. The first isolation pillar 6 is in a ring shape and has a relatively high height, which can prevent water and oxygen from entering the display region 1 from the opening region 3.

Optionally, as shown in FIG. 4, the first isolation pillar 6 is in the same layer as the first source-drain electrode layer 35. The first isolation pillar 6 has a first sublayer, a second sublayer, and a third sublayer that are stacked in sequence in a direction away from the base substrate 17. In the direction from the opening region 3 to the display region 1, compared with the first sublayer and the third sublayer, both sides of the second sublayer are retracted, such that the cross-section of the first isolation pillar 6 is in the shape of an “I”. This is to ensure that when manufacturing the film layer on the side of the first isolation pillar 6 away from the base substrate 17, such as the passivation layer 12 and the first electrode layer 21, the two protruding sides of the third sublayer compared to the second sublayer in the I-shaped structure can naturally separate these film layers, saving process costs.

Optionally, the first source-drain electrode layer 35 and the second source-drain electrode layer 37 include a molybdenum layer, an aluminum layer, and a molybdenum layer that are stacked in sequence, and accordingly, the first sublayer and the third sublayer are molybdenum layers, and the second sublayer is an aluminum layer. Alternatively, the first source-drain electrode layer 35 and the second source-drain electrode layer 37 include a plurality of metal films such as a titanium layer, an aluminum layer, and a titanium layer that are stacked in sequence, and accordingly, the first sublayer and the third sublayer are titanium layers, and the second sublayer is an aluminum layer.

Optionally, the first insulation structure 121 is in the same layer as the passivation layer 12. The first insulation structure 121 is arranged between the conductive first isolation pillar 6 and the first isolation ring 211, such that the first isolation ring 211 and the first isolation pillar 6 are not electrically connected. At the same time, for two adjacent first isolation structures G1, this arrangement can avoid the overlap of the two first isolation rings 211 in the two first isolation structures G1, such that the first isolation ring 211 is in a floating state, that is, a state where no power is loaded, such that the electrostatic protection structure 11 is used to protect the first isolation ring 211.

In the embodiments of the present disclosure, the base substrate 17 may be any transparent substrate, such as a glass substrate, a quartz substrate, a plastic substrate, other transparent hard substrates or other transparent flexible substrates, which can be a single layer or a multilayer structure. Taking a multilayer structure as an example, the base substrate 17 includes a first polyimide (PI) layer, a first protective layer, a second PI layer, and a second protective layer that are stacked in sequence from bottom to top. The two protective layers are used to protect the PI layer to prevent subsequent processes from damaging the PI layer. The second protective layer is also covered with a buffer layer, which can block water, oxygen, and alkaline ions.

Exemplarily, the material of the light shielding layer 13 may be a metal material, including but not limited to molybdenum, aluminum, titanium, copper and other materials. The light shielding layer 13 can reduce the light received by the thin film transistor (TFT) and can also conduct electricity. The light shielding layer 13 can also be referred to as a bottom shield metal (BSM) layer.

Exemplarily, the first active layer 19 is made of low-temperature polysilicon material, and the second active layer 39 is made of metal oxide semiconductor materials such as indium gallium zinc oxide (IGZO).

Exemplarily, the first gate insulating layer 30, the first insulating layer 31, the second gate insulating layer 32, the third gate insulating layer 33, the interlayer dielectric layer 34, and the touch insulating layer 43 may be made of silicon oxide or silicon nitride, silicon oxynitride or the like.

Exemplarily, the first gate layer 14 and the second gate layer 15 are made of metal materials, such as one or more of molybdenum, copper, and aluminum.

Exemplarily, the third gate layer 16 includes a first sub-gate layer and a second sub-gate layer that are stacked. The first sub-gate layer is made of a transparent conductive material, such as indium tin oxide (ITO); the second sub-gate layer is made of a metal material, which can be a single metal layer or a plurality of metal layers stacked in sequence. The metal material used in the metal layer in the second sub-gate layer may be titanium, aluminum, titanium, etc.

Exemplarily, the material of the passivation layer 12 may be a silicon oxide layer, a silicon nitride layer, or a silicon oxide layer.

Exemplarily, the first planarization layer 36 and the second planarization layer 38 are made of organic insulating materials, such as resin.

Exemplarily, the material of the pixel definition layer 22 includes one or more of polyimide, polyphthalimide, polyphthalamide, silicon oxide, silicon nitride, and the like.

Exemplarily, the second electrode layer may be made of a metal material, such as gold, or the second electrode layer may be made of a transparent conductive material, such as ITO.

Exemplarily, the light-emitting layer 23 may include a hole transport layer (HTL), a hole injection layer (HIL), an electron transport layer (ETL), an electron injection layer (EIL), a hole blocking layer (HBL), an electron blocking layer (EBL), and a light-emitting material layer.

Exemplarily, the first electrode layer 21 is made of a metal material such as magnesium-silver alloy, or made of a transparent conductive material, such as ITO.

Exemplarily, the first inorganic encapsulation layer 40 and the second inorganic encapsulation layer 42 are made of silicon nitride, silicon oxide, or silicon oxynitride. The first organic encapsulation layer 41 and the second organic encapsulation layer 45 are made of organic insulating materials, and here, the organic insulating materials include materials such as polyimide, polyamide, acrylic resin, benzocyclobutene, hexamethyldisiloxane (HMDSO), and phenolic resin.

Exemplarily, the touch organic protection layer 44 is made of thermosetting or photocurable organic material such as acrylates, epoxy resins. The touch organic protection layer 44 may also be referred to as a touch organic coating (TOC) layer.

In the embodiments of the present disclosure, as shown in FIG. 4, the base substrate 17 also has a second isolation region 4, and the second isolation region 4 is disposed between the first isolation region 2 and the opening region 3. The display panel 100 also includes a plurality of external isolation structures disposed in the second isolation region 4 and on the first surface D. The plurality of external isolation structures located in the second isolation region 4 include at least one second isolation structure G2, and the second isolation structure G2 has the same structure as the first isolation structure G1. The arrangement of the second isolation region 4 can further prevent the invasion of water and oxygen into the display region, meanwhile the arrangement of the second isolation region 4 facilitates the manufacture of the opening region 3.

The second isolation structure G2 includes a second isolation ring 212, a second insulation structure 122, and a second isolation pillar 7. The second isolation ring 212 is in the same layer as the first electrode 21 and the first isolation ring 211 and is insulated from the first electrode 21 and the first isolation ring 211. The second isolation pillar 7 has a top surface away from the base substrate 17, a bottom surface close to the base substrate 17, and a second sidewall connecting the top surface and the bottom surface. The second sidewall faces towards the opening region 3. The second insulation structure 122 includes a third insulation portion 1221 and a fourth insulation portion 1222 that are connected. The third insulation portion 1221 is disposed on the top surface of the second isolation pillar 7, and the fourth insulation portion 1222 is disposed on the second sidewall. The second isolation ring 212 includes a third conductive portion 2121 and a fourth conductive portion 2122 that are connected in sequence. The third conductive portion 2121 is disposed on the surface of the third insulation portion 1221 away from the base substrate 17, and the fourth conductive portion 2122 is disposed on the surface of the fourth insulation portion 1222 facing towards the opening region 3.

In the embodiments of the present disclosure, as shown in FIG. 4, the plurality of internal isolation structures in the first isolation region 2 also include a third isolation structure G3. The third isolation structure G3 includes a third insulation structure 123, a third isolation pillar 8, and a third isolation ring 216 that are arranged in sequence from close to the base substrate 17 to away from the base substrate 17, the third isolation ring 216 are in the same layer as the first electrode 21 and the first isolation ring 211 and is insulated from the first electrode 21 and the first isolation ring 211, and the third isolation pillar 8 is in the same layer as the second source-drain layer 37. The third isolation structure G3 can also prevent water and oxygen from entering.

It should be noted that, in other embodiments, the first isolation region 2 may not include the third isolation structure G3, and all internal isolation structures are the first isolation structures 6.

In addition, it should be noted that, in other embodiments, the structure of the second isolation structure G2 may also be the same as the structure of the third isolation structure G3.

In the embodiments of the present disclosure, as shown in FIG. 4, the plurality of external isolation structures in the second isolation region 4 also include a fourth isolation structure G4. The height of the fourth isolation structure G4 is greater than the heights of other external isolation pillars in the second isolation region 4. The fourth isolation structure G4 is higher than other external isolation structures and can better prevent water and oxygen from entering the display region. Therefore, the fourth isolation structure G4 is usually arranged in the second isolation region 4 close to the opening region 3.

Exemplarily, the fourth isolation structure G4 includes a fourth insulation structure 124, a fourth isolation pillar 9a, a fifth isolation pillar 9b, and a fourth isolation ring 217 arranged in sequence from close to the base substrate 17 to away from the base substrate 17, and the fourth isolation ring 217 is in the same layer as the first electrode 21 and the first isolation ring 211 and is insulated from the first electrode 21 and the first isolation ring 211. The fourth isolation structure G4 includes two isolation pillars, so it is higher than other external isolation structures, and can better prevent water and oxygen from entering the display region. Optionally, the fourth isolation pillar 9a is in the same layer as the first source-drain electrode layer 35, and the fifth isolation pillar 9b is in the same layer as the second source-drain electrode layer 37. Optionally, before manufacturing the opening region 3, the region corresponding to the opening region 3 is a solid structure and has a plurality of annular isolation structures, and the second isolation region 4 is connected to the solid structure. The distance between the isolation structure closest to the solid structure in the second isolation region 4 and the isolation structure closest to the second isolation region 4 in the solid structure can be designed to be larger, such as larger than the distance between the two adjacent isolation structures in the second isolation region, so as to facilitate segmentation in the two isolation structures to obtain the opening region 3.

Optionally, as shown in FIG. 4, the electrostatic protection structure 11 may also cover the external isolation pillars in the second isolation region 4. That is, orthographic projections of the external isolation pillars on the first surface D are also within an orthographic projection of the electrostatic protection structure 11 on the first surface D.

Optionally, the electrostatic protection structure in the second isolation region 4 is integrated with the electrostatic protection structure in the first isolation region 2. For example, in FIG. 4, each electrostatic shielding ring 1111a covers both the first isolation region 2 and the second isolation region 4.

Alternatively, the electrostatic protection structure in the second isolation region 4 and the electrostatic protection structure in the first isolation region 2 may also be arranged in sections. For example, in FIG. 5, each electrostatic shielding layer 1111 includes a plurality of electrostatic shielding rings 1111a, and each electrostatic shielding ring 1111a corresponds to one isolation structure.

Optionally, the display panel 100 also includes an isolation dam 5. The isolation dam 5 is disposed between the first isolation region 2 and the second isolation region 4, and the isolation dam 5 is disposed on the first surface D. The arrangement of the isolation dam 5 can further prevent water and oxygen from entering the display region to cause poor display.

In the embodiments shown in FIG. 4, the distance between two adjacent isolation structures in the first isolation region 2 is smaller than the distance between two adjacent isolation structures in the second isolation region 4. The radial dimension of the isolation ring is about 500 μm larger than the radial dimension of the isolation pillar. In other possible embodiments, the distance between two adjacent isolation structures in the first isolation region 2 is smaller than the distance between two adjacent isolation structures in the second isolation region 4. For example, the spacing between two adjacent isolation structures in the first isolation region 2 is about 7.5 μm, and the spacing between two adjacent isolation structures in the second isolation region 4 is about 9.0 μm.

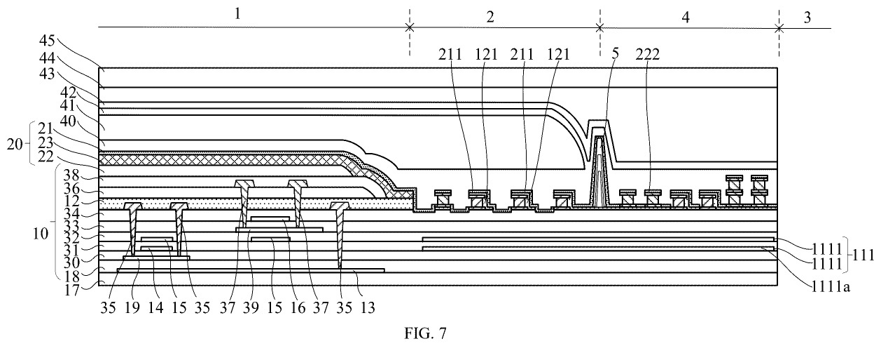

FIG. 6 is a schematic cross-sectional structure diagram of another display panel according to some embodiments of the present disclosure. Compared with the embodiments shown in FIG. 4, the difference is that the structure of the electrostatic protection structure 11 is different. In the embodiments shown in FIG. 6, each electrostatic shielding layer 111 has a plurality of electrostatic shielding rings 1111a, which continuously cover the plurality of first isolation structures G1 in the first isolation region 2, and discontinuously cover the plurality of isolation structures in the second isolation region 4. It not only focuses on protecting the first isolation rings 211 in the first isolation region 2 that is prone to breakdown, but also protects the second isolation rings 212 in the second isolation region 4 under the premise of saving costs as much as possible.

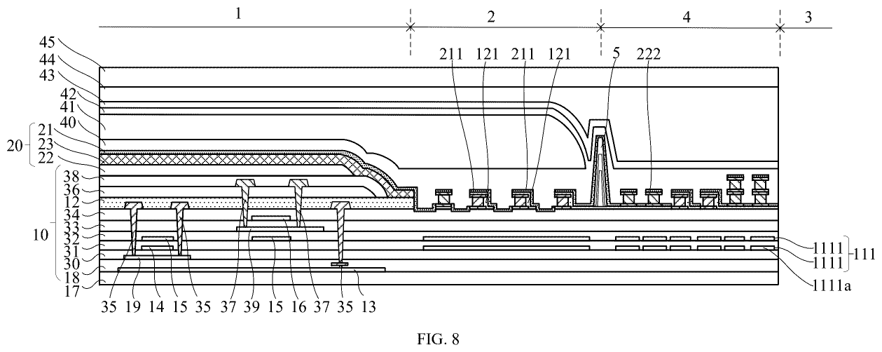

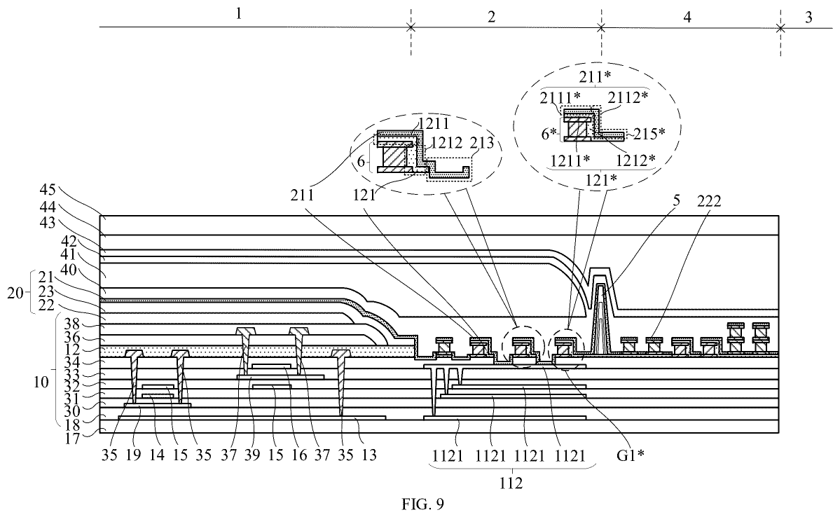

FIGS. 7 and 8 are schematic cross-sectional structure diagrams of another display panel according to some embodiments of the present disclosure. The display panel in FIGS. 7 and 8 adopts an LTPS backplane, that is, in FIGS. 7 and 8, the plurality of TFTs included in the driver circuit layer 10 are low-temperature polysilicon TFTs. For the LTPS backplane, the non-insulating layer includes at least one of a first gate layer 14 and a second gate layer 15. The electrostatic protection structure 11 is in the same layer as at least one non-insulating layer. The first gate layer 14 and the second gate layer 15 are both film layers on the side of the first isolation structure 6 away from the first electrode layer 21, and can therefore be used to simultaneously manufacture the electrostatic protection structure.

Exemplarily, the LTPS backplane includes a base substrate 17, a first gate layer 14, a buffer layer 18, a first active layer 19, a first gate insulating layer 30, a second gate layer 15, an interlayer dielectric layer 34, a first source-drain layer 35, a passivation layer 12, and a first planarization layer 36 that are stacked in sequence. The light-emitting functional layer 20 includes a second electrode layer, a pixel definition layer 22, a light-emitting layer 23, and a first electrode layer 21 that are stacked in sequence on the first surface D of the drive backplane. The display panel 100 includes a drive backplane, a light-emitting functional layer 20, and a first inorganic encapsulation layer 40, a first organic encapsulation layer 41, a second inorganic encapsulation layer 42, a touch insulating layer 43, a second organic encapsulation layer 44, and a touch layer 45 that are stacked in sequence on a side of the light-emitting functional layer 20 away from the first surface D.

Exemplarily, the first active layer 19 is made of polysilicon material.

Exemplarily, the first gate layer 14 is made of a metal material, such as one or more of molybdenum, copper, and aluminum.

Optionally, the first gate layer 14 and the second gate layer 15 may also be disposed on a side of the first active layer away from the base substrate.

In the embodiments shown in FIG. 7 and FIG. 8, the materials for making other layers refer to the embodiments shown in FIG. 4 above, and will not be described in detail here.

In the embodiments shown in FIG. 7, the electrostatic protection structure 11 includes two electrostatic shielding layers 111 that are respectively in the same layer as the first gate layer 14 and the second gate layer 15, and each electrostatic shielding layer 111 includes one electrostatic shielding ring 1111a, which fully covers the plurality of isolation structures in the first isolation region 2 and the second isolation region 4.

In the embodiments shown in FIG. 8, the electrostatic protection structure 11 includes two electrostatic shielding layers 111 that are respectively in the same layer as the first gate layer 14 and the second gate layer 15, and each electrostatic shielding layer 111 includes a plurality of electrostatic shielding rings 1111a. The electrostatic shielding layer 111 fully covers the plurality of first isolation structures 6 in the first isolation region 2 (i.e., the electrostatic shielding layer 1111 in the first isolation region 2 includes only one electrostatic shielding ring 1111a), and covers the plurality of isolation structures in the second isolation region 4 in sections (i.e., the electrostatic shielding layer 1111 in the second isolation region 4 includes a plurality of electrostatic shielding rings 1111a that are concentrically arranged).

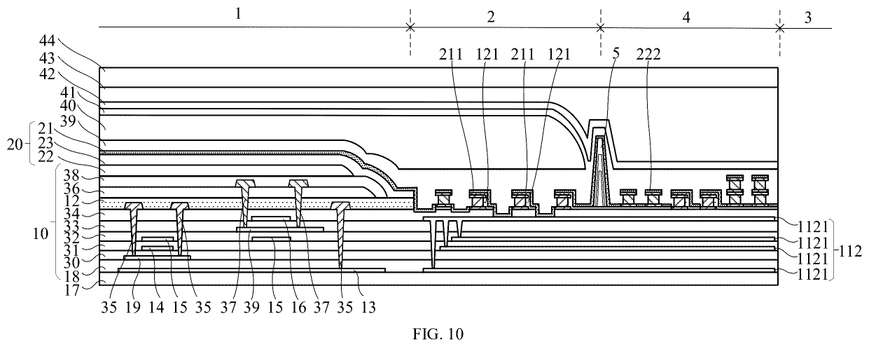

FIG. 9 is a schematic cross-sectional structure diagram of another display panel according to some embodiments of the present disclosure. Compared with the embodiments shown in FIG. 4, the difference is that in the embodiments shown in FIG. 9, the electrostatic protection structure 11 is an electrostatic discharge structure 112, and the first isolation ring 211 is electrically connected to the electrostatic discharge structure 112. The first isolation ring 211 is electrically connected to the electrostatic discharge structure 112 to release static electricity, thereby preventing breakdown at the first isolation ring 211.

Exemplarily, the electrostatic discharge structure 112 includes one electrostatic discharge layer 1121, or the electrostatic discharge structure 112 includes a plurality of electrostatic discharge layers 1121, and the plurality of electrostatic discharge layers 1121 are stacked in a direction perpendicular to the first surface D and connected to each other. The number of the electrostatic discharge layers 1121 can be designed as needed, and the excess charge on the first isolation ring 211 can be released to the signal source through the electrostatic discharge layer 1121. The electrostatic discharge layer 1121 is a complete ring structure.

Each electrostatic discharge layer 1121 is electrically connected to a voltage signal source. Exemplarily, the electrostatic discharge structure 112 can be electrically connected to a voltage signal source through a signal line in the display region.

Optionally, the voltage signal source is used to provide a first voltage signal VDD or a second voltage signal VSS, with the first voltage signal VDD being greater than the second voltage signal VSS. Optionally, the light-emitting unit includes an anode and a cathode, the first voltage signal VDD is used to input the anode, the second voltage signal VSS is used to input the cathode, and the voltage difference between the first voltage signal and the second voltage signal is used to drive the light-emitting unit to emit light.

Exemplarily, an orthographic projection of the first isolation structure G1 on the first surface D is within an orthographic projection of the electrostatic discharge layer 1121 on the first surface D. The electrostatic discharge layer 1121 is not only electrically connected to the first isolation ring 211, but also guides away the excess charge on the first isolation ring 211, thereby protecting the first isolation ring 211; the electrostatic discharge layer 112 also covers the conductive first isolation pillar 6, thereby preventing the accumulation of excessive charge on the first isolation pillar 6 and protecting the first isolation pillar 6.

Exemplarily, as shown in FIG. 9, the electrostatic discharge structure 112 includes four electrostatic discharge layers 1121, and the electrostatic discharge layer 1121 farthest from the first surface D is connected to other electrostatic discharge layers 1121 through via holes.

In the embodiments, an orthographic projection of the electrostatic discharge layer 1121 farthest from the first surface D on the first surface includes orthographic projections of other electrostatic discharge layers 1121 on the first surface D. And along the direction from the isolation pillar of the first isolation region 2 to the base substrate 17, in the two adjacent electrostatic discharge layers 1121, an orthographic projection of the electrostatic discharge layer 1121 away from the base substrate 17 on the first surface D is inside an orthographic projection of the electrostatic discharge layer 1121 close to the base substrate 17 on the first surface D. That is, the areas of different electrostatic discharge layers 1121 are different, which facilitates the arrangement of via holes to electrically connect different electrostatic discharge layers 1121, and the via holes in different layers connected to other layers are staggered.

In the embodiments of the present disclosure, as shown in FIG. 9, the display panel 100 also includes a first bottom isolation ring 213. The first bottom isolation ring 213 is disposed between two adjacent first isolation structures G1 and connected to the second conductive portion 2112 of the first isolation structure G1 close to the display region 1. An orthographic projection of at least a portion of the first bottom isolation ring 213 on the second surface is located on a side of an orthographic projection of the first isolation ring 211 on the second surface close to the base substrate 17, with the second surface being perpendicular to the first surface. The distance from the first bottom isolation ring 213 to the electrostatic discharge layer 1121 below is closer than the distance from the first isolation ring 211 to the electrostatic discharge layer 1121 below, such that the first isolation ring 211 of the first isolation structure G1 is electrically connected to the electrostatic discharge structure 112 through the first bottom isolation ring 213.

In some examples, the touch insulating layer 43 has a plurality of annular grooves, which penetrate the touch insulating layer 43. The first bottom isolation ring 213 is disposed in the corresponding annular grooves, thereby being connected to the electrostatic discharge structure 112.

Optionally, as shown in FIG. 9, the second isolation region 4 does not have a structure similar to the first bottom isolation ring 213.

Optionally, as shown in FIG. 9, the display panel 100 also includes an isolation dam 5. The isolation dam 5 is disposed between the first isolation region 2 and the second isolation region 4, and is disposed on the first surface. The isolation dam 5 can further prevent water and oxygen from entering the display region to cause poor display.

Exemplarily, the edge isolation structure G1* is the closest to the opening region 3 among the plurality of internal isolation structures in the first isolation region 2. The edge isolation structure G1* includes an edge isolation pillar 6*, an edge insulation structure 121*, and an edge isolation ring 211*. The edge isolation pillar 6* has a top surface away from the base substrate 17, a bottom surface close to the base substrate 17, and a first sidewall connecting the top surface and the bottom surface, the first sidewall faces towards the opening region 3. The edge insulation structure 121* includes a first edge insulation portion 1211* and a second edge insulation portion 1212* that are connected, the first edge insulation portion 1211* is disposed on the top surface, the second edge insulation portion 1212* is disposed on the first sidewall, and the second edge insulation portion 1212* is connected to the insulation block disposed on a side of the isolation dam 5 close to the base substrate 17. The edge isolation ring 211* includes a first edge conductive portion 2111* and a second edge conductive portion 2112* that are connected in sequence. The first edge conductive portion 2111* is disposed on a surface of the first edge insulation portion 1211* away from the base substrate 17, the second edge conductive portion 2112* is disposed on a surface of the second edge insulation portion 1212* facing towards the opening region 3, and a side of the second edge conductive portion 2112* away from the first edge conductive portion 2111* is connected to an electrode block disposed on a side of the isolation dam 5 away from the base substrate 17.

The display panel 100 also includes an edge bottom isolation ring 215*. The edge bottom isolation ring 215* is disposed on a side of the edge isolation structure close to the opening region 3. The edge bottom isolation ring 215* is connected to the second edge conductive portion 2112* of the edge isolation structure G1* and extends in the direction of the opening region 3*. An orthographic projection of the edge bottom isolation ring 215* on the second surface is within an orthographic projection of the first edge isolation ring 211* of the edge isolation structure G1* on the second surface. Compared with the first bottom isolation ring 213, the plane where the edge bottom isolation ring 215* is located can be parallel to the first surface D. In the direction from the opening region 3 to the display region 1, the size of the edge bottom isolation ring 215* can be smaller than the size of the first bottom isolation ring 213. That is, this design of the edge bottom isolation ring 215* can reduce the distance between the edge isolation structure G1* and the isolation dam 5, thereby achieving the effect of a narrow bezel.

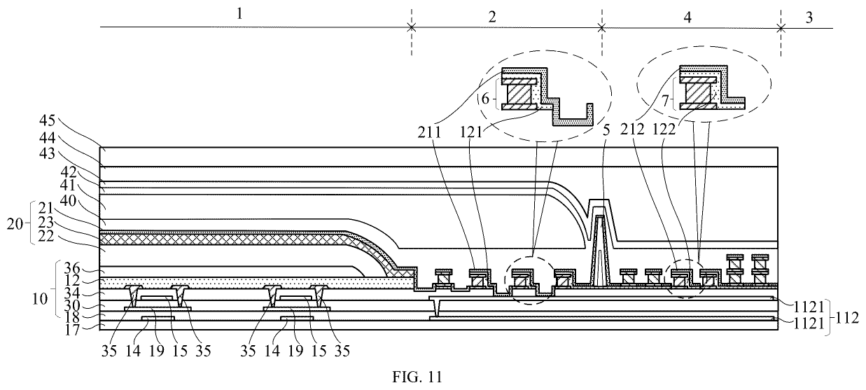

Compared with the embodiments shown in FIG. 9, in the embodiments shown in FIG. 10, the electrostatic protection structure 11 includes four electrostatic discharge layers 112, and the four electrostatic discharge layers 112 simultaneously cover the plurality of internal isolation structures in the first isolation region 2 and the plurality of external isolation structures in the second isolation region 4.

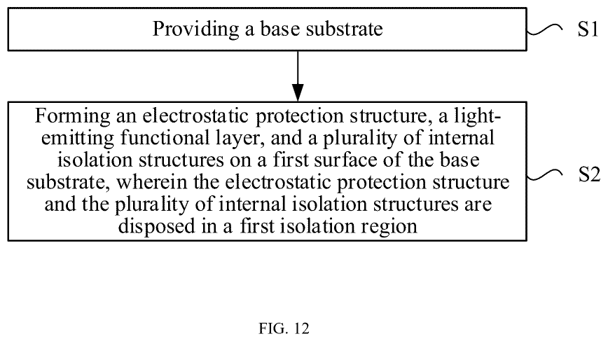

In the embodiments shown in FIG. 11, the drive backplane is an LTPS backplane, and the electrostatic protection structure 11 includes two electrostatic discharge layers 112.

Optionally, the display panel 100 may include both the electrostatic shielding layer 111 and the electrostatic discharge layer 112, for example, the electrostatic discharge layer 112 covers the first isolation region 2, and the electrostatic shielding layer 111 fully covers or partially covers the second isolation region 4.

Optionally, the number of electrostatic discharge layers in the first isolation region 2 and the number of electrostatic shielding layers in the second isolation region 4 may be the same or different.

A method for manufacturing a display panel is also provided in the present disclosure. FIG. 12 is a flowchart of a method for manufacturing a display panel according to some embodiments of the present disclosure. As shown in FIG. 12, the method includes:

In step S1, a base substrate is provided.

The base substrate has a display region, a first isolation region, and an opening region. The display region surrounds the opening region, and the first isolation region is disposed between the opening region and the display region.

In step S2, an electrostatic protection structure, a light-emitting functional layer, and a plurality of internal isolation structures are formed on a first surface of the base substrate.

The light-emitting functional layer includes a plurality of light-emitting units arranged in an array in the display region, the first electrodes of the plurality of light-emitting units are connected, the plurality of internal isolation structures are disposed in the first isolation region, the plurality of isolation structures are all in a ring shape and surround the opening region, the plurality of internal isolation structures include at least one first isolation structure, the first isolation structure includes a first isolation ring, the first isolation ring is in the same layer as the first electrode and is insulated from the first electrode, the electrostatic protection structure is disposed in the first isolation region on a side of the plurality of internal isolation structures close to the base substrate, and the electrostatic protection structure is used to prevent the first isolation ring from accumulating charge.

Taking the structure shown in FIG. 4 as an example, the following provides an exemplary description of step S2. Exemplarily, step S2 may include:

In the first step, a light-shielding metal layer is deposited on the base substrate. Then, through processes such as photoresist coating, exposure, and development, a photoresist structure is obtained. Using this photoresist structure as a mask, the light-shielding metal layer is etched to form a light-shielding pattern layer. The light-shielding pattern layer includes a light-shielding layer in the display region and an electrostatic shielding layer in the first isolation region and the second isolation region.

In the second step, a buffer layer is formed on the light-shielding pattern layer. For example, the buffer layer can be formed on the light-shielding pattern layer by deposition. Then, a first active layer is formed on the buffer layer. For example, an initial first active layer can be first deposited on the buffer layer. A photoresist structure is obtained through processes such as photoresist coating, exposure, and development. Using this photoresist structure as a mask, the initial first active layer is etched to form the first active layer.

In the third step, an initial first gate insulating layer and an initial first gate layer are sequentially formed on the first active layer by, for example, deposition. The initial first gate insulating layer covers the first active layer. A photoresist structure is obtained on the initial first gate layer through processes such as photoresist coating, exposure, and development. Using this photoresist structure as a mask, the initial first gate layer is etched to form a first gate pattern layer. The first gate pattern layer includes a first gate layer located in the first isolation region and an electrostatic shielding layer located in the first isolation region and the second isolation region. Optionally, a portion of the first active layer not covered by the first gate layer is made conductive to ensure good ohmic contact between the first active layer and the first source-drain layer to be subsequently formed.

In the fourth step, an initial first insulating layer and an initial second gate layer are subsequently formed on the first gate pattern layer by, for example, deposition. A photoresist structure is obtained on the initial second gate layer through processes such as photoresist coating, exposure, and development. Using this photoresist structure as a mask, the initial second gate layer is etched to form a second gate pattern layer. The second gate pattern layer includes a second gate layer located in the first isolation region and an electrostatic shielding layer located in the first isolation region and the second isolation region.

In the fifth step, an initial second gate insulating layer and an initial second active layer are subsequently formed on the second gate pattern layer by, for example, deposition. Then, a photoresist structure is obtained through processes such as photoresist coating, exposure, and development. Using this photoresist structure as a mask, the initial second active layer is etched to form the second active layer.

In the sixth step, an initial third gate insulating layer and an initial third gate layer are subsequently formed on the second active layer by, for example, deposition. The initial third gate insulating layer covers the second active layer. A photoresist structure is obtained on the initial third gate layer through processes such as photoresist coating, exposure, and development. Using this photoresist structure as a mask, the initial third gate layer is etched to form a third gate pattern layer. The third gate pattern layer includes a third gate layer located in the first isolation region and an electrostatic shielding layer located in the first isolation region and the second isolation region. Optionally, a portion of the second active layer not covered by the third gate layer is made conductive to ensure good ohmic contact between the second active layer and the second source-drain layer to be subsequently formed.

In the seventh step, an initial interlayer dielectric layer is formed on the third gate layer by, for example, deposition. Through a series of processes such as photoresist coating, exposure, etching, and stripping, a plurality of via holes exposing the light shielding layer are formed, and simultaneously, the first gate insulating layer is obtained from the initial first gate insulating layer. Subsequently, through another series of processes including photoresist coating, exposure, etching, and stripping, a plurality of via holes exposing the first active layer are formed. Simultaneously, the first insulating layer is obtained from the initial first insulating layer, the second gate insulating layer is obtained from the initial second gate insulating layer, and the interlayer dielectric layer is obtained.

In the eighth step, in the via holes exposing light shielding layer and the first active layer obtained by etching in the seventh step, a first source-drain pattern layer is formed through a series of processes such as deposition, photoresist coating, exposure, etching, and stripping. The first source-drain pattern layer includes a first source-drain layer located in the display region, a first isolation pillar located in the first isolation region, and a second isolation pillar located in the second isolation region.

In the ninth step, an initial passivation layer and an initial first planarization layer are formed on the first source-drain pattern layer by, for example, deposition. Through a series of processes such as photoresist coating, exposure, etching, and stripping, a plurality of via holes exposing the second active layer are formed. Simultaneously, a third gate insulation layer is obtained from the initial third gate insulation layer, a passivation layer located in the display region, a first insulation structure located in the first isolation region, and a second insulation structure located in the second isolation region are obtained from the initial passivation layer, and a first planarization layer is obtained from the initial first planarization layer.

In the tenth step, in the via holes exposing the second active layer obtained by etching in the ninth step, a second source-drain pattern layer is formed through a series of processes such as deposition, photoresist coating, exposure, etching, and stripping. The second source-drain pattern layer includes a second source-drain layer located in the display region, and isolation structures partially located in the first isolation region and the second isolation region except the first isolation structure and the second isolation structure.

In the eleventh step, a second planarization layer is formed on the second source-drain pattern layer by, for example, deposition.

The materials of each layer refer to the above embodiments and will not be described in detail here.

The above are only optional embodiments of the present disclosure and are not intended to limit the present disclosure. Any modifications, equivalent substitutions, improvements, etc. made within the spirit and principles of the present disclosure should be included in the protection scope of the present disclosure.

1. A display panel, comprising a base substrate, a light-emitting functional layer, an electrostatic protection structure, and a plurality of internal isolation structures; wherein
the base substrate has a display region, a first isolation region, and an opening region, wherein the display region surrounds the opening region, and the first isolation region is disposed between the opening region and the display region;
the light-emitting functional layer is disposed on a first surface of the base substrate and comprises a plurality of light-emitting units, wherein the plurality of light-emitting units are arranged in an array in the display region, and first electrodes of the plurality of light-emitting units are connected;
the plurality of internal isolation structures are disposed in the first isolation region and on the first surface, the plurality of internal isolation structures are all in a ring shape and surround the opening region, and the plurality of internal isolation structures comprise at least one first isolation structure comprising a first isolation ring, wherein the first isolation ring is in a same layer as the first electrodes and is insulated from the first electrodes; and
the electrostatic protection structure is disposed at least in the first isolation region and on a side of the plurality of internal isolation structures close to the base substrate.

2. The display panel according to claim 1, wherein the electrostatic protection structure is an electrostatic shielding structure;
wherein an orthographic projection of the first isolation structure on the first surface is within an orthographic projection of the electrostatic shielding structure on the first surface.

3. The display panel according to claim 2, wherein the electrostatic shielding structure comprises one electrostatic shielding layer, or comprises a plurality of electrostatic shielding layers stacked in a direction perpendicular to the first surface;
wherein the electrostatic shielding layer comprises an electrostatic shielding ring.

4. The display panel according to claim 1, wherein the electrostatic protection structure is an electrostatic discharge structure, and the first isolation ring is electrically connected to the electrostatic discharge structure.

5. The display panel according to claim 4, wherein the electrostatic discharge structure comprises one electrostatic discharge layer or comprises a plurality of electrostatic discharge layers that are stacked in a direction perpendicular to the first surface and are connected to each other; and
each of the electrostatic discharge layers is electrically connected to a voltage signal source.

6. The display panel according to claim 1, wherein the display panel further comprises a driver circuit layer, wherein the driver circuit layer is disposed between the light-emitting functional layer and the base substrate; and
the electrostatic protection structure is in a same layer as at least one non-insulating layer of the driver circuit layer.

7. The display panel according to claim 6, wherein the driver circuit layer comprises a plurality of thin film transistors;
wherein the plurality of thin film transistors comprises low-temperature polycrystalline silicon thin film transistors and metal oxide thin film transistors, and the at least one non-insulating layer comprises at least one of a shading layer, a first gate layer, a second gate layer, and a third gate layer.

8. The display panel according to claim 2, wherein the first isolation structure further comprises a first isolation pillar and a first insulation structure;
wherein the first isolation pillar has a top surface away from the base substrate a bottom surface close to the base substrate, and a first sidewall connecting the top surface and the bottom surface, and the first sidewall faces towards the opening region;
the first insulation structure comprises a first insulation portion and a second insulation portion that are connected, wherein the first insulation portion is disposed on the top surface, and the second insulation portion is disposed on the first sidewall; and
the first isolation ring comprises a first conductive portion and a second conductive portion that are connected in sequence, wherein the first conductive portion is disposed on a surface of the first insulation portion away from the base substrate, and the second conductive portion is disposed on a surface of the second insulation portion facing towards the opening region.

9. The display panel according to claim 4, wherein the first isolation structure further comprises a first isolation pillar and a first insulation structure;
wherein the first isolation pillar has a top surface away from the base substrate, a bottom surface close to the base substrate, and a first sidewall connecting the top surface and the bottom surface, and the first sidewall faces towards the opening region;
the first insulation structure comprises a first insulation portion and a second insulation portion that are connected, wherein the first insulation portion is disposed on the top surface, and the second insulation portion is disposed on the first sidewall; and
the first isolation ring comprises a first conductive portion and a second conductive portion that are connected in sequence, wherein the first conductive portion is disposed on a surface of the first insulation portion away from the base substrate, the second conductive portion is disposed on a surface of the second insulation portion facing toward the opening region, and the second conductive portion is electrically connected to the electrostatic discharge structure.

10. The display panel according to claim 8, or wherein the display panel further comprises an isolation dam, wherein the isolation dam is disposed between the first isolation region and the opening region, and the isolation dam is disposed on the first surface; and
an internal isolation structure among the plurality of internal isolation structures that is closest to the opening region is an edge isolation structure;
wherein the edge isolation structure comprises an edge isolation pillar, an edge insulation structure, and an edge isolation ring, wherein the edge isolation pillar has a top surface away from the base substrate, a bottom surface close to the base substrate, and a first sidewall connecting the top surface and the bottom surface; the first sidewall faces towards the opening region; and the edge insulation structure comprises a first edge insulation portion and a second edge insulation portion that are connected, wherein the first edge insulation portion is disposed on the top surface, the second edge insulation portion is disposed on the first sidewall, the second edge insulation portion is connected to an insulation block disposed on a side of the isolation dam close to the base substrate; and
the edge isolation ring comprises a first edge conductive portion and a second edge conductive portion that are connected in sequence, wherein the first edge conductive portion is disposed on a surface of the first edge insulation portion away from the base substrate, the second edge conductive portion is disposed on a surface of the second edge insulation portion facing towards the opening region, and a side of the second edge conductive portion away from the first edge conductive portion is connected to an electrode block disposed on a side of the isolation dam away from the base substrate.

11. The display panel according to claim 8, wherein the base substrate further has a second isolation region disposed between the first isolation region and the opening region, and the display panel further comprises a plurality of external isolation structures disposed in the second isolation region and on the first surface; and
wherein the plurality of external isolation structures comprises at least one second isolation structure, and the second isolation structure is of a same structure as the first isolation structure.

12. The display panel according to claim 1, to wherein the base substrate further has a second isolation region disposed between the first isolation region and the opening region, and the display panel further comprises a plurality of external isolation structures disposed in the second isolation region and on the first surface; and
wherein an orthographic projection of at least a portion of the plurality of external isolation structures is within an orthographic projection of the electrostatic protection structure on the first surface.

13. The display panel according to claim 12, wherein the plurality of external isolation structures further comprises a fourth isolation structure, and a height of the fourth isolation structure is greater than heights of external isolation pillars except the fourth isolation structure.

14. A method for manufacturing a display panel, comprising:
providing a base substrate, wherein the base substrate has a display region, a first isolation region, and an opening region, wherein the display region surrounds the opening region, and the first isolation region is disposed between the opening region and the display region; and
forming a light-emitting functional layer, an electrostatic protection structure, and a plurality of internal isolation structures on a first surface of the base substrate;
wherein the light-emitting functional layer comprises a plurality of light-emitting units arranged in an array in the display region, first electrodes of the plurality of light-emitting units being connected, the plurality of internal isolation structures are disposed in the first isolation region, the plurality of internal isolation structures are all in a ring shape and surround the opening region, the plurality of internal isolation structures comprise at least one first isolation structure, the first isolation structure comprises a first isolation ring, wherein the first isolation ring is in a same layer as the first electrodes and is insulated from the first electrodes, and the electrostatic protection structure is disposed in the first isolation region and on a side of the plurality of internal isolation structures close to the base substrate.

15. A display device, comprising a power supply circuit and a display panel, wherein the power supply circuit supplies power to the display panel; and
the display panel comprises a base substrate, a light-emitting functional layer, an electrostatic protection structure, and a plurality of internal isolation structures; wherein
the base substrate has a display region, a first isolation region, and an opening region, wherein the display region surrounds the opening region, and the first isolation region is disposed between the opening region and the display region;
the light-emitting functional layer is disposed on a first surface of the base substrate and comprises a plurality of light-emitting units, wherein the plurality of light-emitting units are arranged in an array in the display region, and first electrodes of the plurality of light-emitting units are connected;
the plurality of internal isolation structures are disposed in the first isolation region and on the first surface, the plurality of internal isolation structures are all in a ring shape and surround the opening region, and the plurality of internal isolation structures comprise at least one first isolation structure comprising a first isolation ring, wherein the first isolation ring is in a same layer as the first electrodes and is insulated from the first electrodes; and
the electrostatic protection structure is disposed at least in the first isolation region and on a side of the plurality of internal isolation structures close to the base substrate.

16. The display panel according to claim 2, wherein the electrostatic shielding structure comprises one electrostatic shielding layer, or comprises a plurality of electrostatic shielding layers stacked in a direction perpendicular to the first surface;
wherein the electrostatic shielding layer comprises a plurality of electrostatic shielding rings, the plurality of electrostatic shielding rings being concentric rings and orthographic projection of the plurality of electrostatic shielding rings on the first surface do not overlap each other.

17. The display panel according to claim 6, wherein the driver circuit layer comprises a plurality of thin film transistors;
wherein the plurality of thin film transistors comprises low-temperature polycrystalline silicon thin film transistors, and at least one the non-insulating layer comprises at least one of a first gate layer and a second gate layer.

18. The display device according to claim 15, wherein the electrostatic protection structure is an electrostatic shielding structure;
wherein an orthographic projection of the first isolation structure on the first surface is within an orthographic projection of the electrostatic shielding structure on the first surface.

19. The display device according to claim 18, wherein the electrostatic shielding structure comprises one electrostatic shielding layer, or comprises a plurality of electrostatic shielding layers stacked in a direction perpendicular to the first surface;
wherein the electrostatic shielding layer comprises an electrostatic shielding ring.

20. The display device according to claim 15, wherein the electrostatic protection structure is an electrostatic discharge structure, and the first isolation ring is electrically connected to the electrostatic discharge structure.
